(19) United States
(12) Patent Application Publication
(10) Pub. No.: US 2013/0125956 A1
(43) Pub. Date: May 23, 2013

(54) MOISTURE-PROOF EXPANSION CHAMBER FOR EQUALIZING PRESSURE IN SEALED CONCENTRATOR PHOTOVOLTAIC SOLAR MODULES

(71) Applicants: Bruce Furman, Durham, NC (US); Etienne Menard, Durham, NC (US); Rudy Bukovnik, Chapel Hill, NC (US); Scott Burroughs, Durham, NC (US)

(72) Inventors: Bruce Furman, Durham, NC (US); Etienne Menard, Durham, NC (US); Rudy Bukovnik, Chapel Hill, NC (US); Scott Burroughs, Durham, NC (US)

(21) Appl. No.: 13/520,911

(22) PCT Filed: Jan. 6, 2011
(86) PCT No.: PCT/US11/20353

§ 371 Date: Feb. 6, 2013

Related U.S. Application Data
(60) Provisional application No. 61/293,069, filed on Jan. 7, 2010.

(51) Int. Cl. H01L 31/048

(52) U.S. Cl. CPC H01L 31/048
USPC 136/251

(57) ABSTRACT

A concentrator-type photovoltaic device includes at least one light receiving module having a plurality of photovoltaic devices therein, and a pressure regulating device comprising a volume-adjustable chamber that is pneumatically coupled to the at least one light receiving module. The volume-adjustable chamber may be configured to expand and contract in response to temperature fluctuations within the at least one light receiving module. The volume-adjustable chamber can be made from a flexible metalized film with a low water vapor transmission rate. In this way the module can remain sealed from water penetration and yet maintain uniform internal pressure during thermal excursions. The volume-adjustable chamber may be combined with a desiccant such that, as air moves into the expansion chamber, it passes over the desiccant, which removes moisture that has penetrated into the sealed module.

### CLAIM OF PRIORITY

This application claims priority from U.S. Provisional Patent Application No. 61/293,069, filed on Jan. 7, 2010, in the United States Patent and Trademark Office, the disclosure of which is incorporated by reference herein in its entirety.

### FIELD

This invention is in the general field of solar power generation. More specifically, the invention relates to sealed enclosures for photovoltaic modules.

### BACKGROUND

With the damaging environmental impact of fossil fuels, imminent shortages and rising costs, pollution-free technologies with long life-cycles are in increasing demand. Accordingly, new generation “green” technologies have been introduced to meet the requirements. Among such new technologies, solar power generation use has increased, leading to the development of new types of concentrator photovoltaic (CPV) modules that have at least one lens placed at a distance from the photovoltaic cell to achieve the desired, focused concentration of light intensity for higher efficiency. However, such a placement creates a gap between the lens and the photovoltaic cell, which may require that the combination lens-photovoltaic cell module be sealed against pollutants to remain effective.

Upon sealing the lens-photovoltaic cell module, the volume of air contained in the gap between the lens and solar cell becomes subject to thermal cycling due to temperature changes that cause expansion and contraction of the air volume in the sealed enclosure, leading to increase and decrease of pressure within the sealed module. The pressure changes can cause distortion of the module causing misalignment of the optics, as well as stressing structural members and seals, causing loss of power output, reduced reliability, maintenance requirements and a decreased lifetime.

Prior art approaches for resolving the problem of pressure changes in sealed CPV modules. One approach is to include venting of the module and another approach is purging the sealed module with a stream of dry gas that is maintained at a small over-pressure. However, venting of modules is not effective because atmospheric moisture can enter the module during the cool down cycle in evenings and during rain and wash-down procedures. The introduction of atmospheric moisture may be detrimental to both the optics and the electrical components. Vents with a membrane such as “Gore-Tex®” will allow the exchange of water vapor, but prevent liquid water from entering the module. Such vents keep out water and dust, but if the humidity level is high enough during the day, condensation will form inside the module during cooler night time periods when the temperature drops below the dew point. In addition, while sealing the module and purging with a dry gas is very effective at regulating the interior pressure and humidity, this approach is expensive as it requires active components such as a dry gas generator, pressure regulator and gas pump.

Some other prior art pertains to photovoltaic cell surface protection and cell efficiency increase where no concentrator lenses are involved, nor gaps created by concentrator cells disposed over photovoltaic cells to increase intensity of the sunlight. For example, U.S. Patent Application Publication No. 2009/0000656 to Elena Shembel et al. entitled “Photovoltaic Module,” involves the use of specially formulated polymers into which anti-static and conducting metal additives have been incorporated to create a flexible, optically transparent cover for mechanical protection of the incident light-facing surface of the photovoltaic cells. The polymer coating imparts higher conversion efficiencies to photovoltaic cells and modules and is resistant to the destructive effects of UV. In one embodiment, the surface comprising a flexible optically transparent polymer cover has a relief or “crinkle coat” structure morphology comprising a random set of rounded ridge and valley features that impart higher conversion efficiencies to photovoltaic cells and modules due to a concentration affect.

Reference is also made to U.S. Pat. No. 5,739,463 to Steve Diaz et al. entitled “Sealed Electronic Packaging For Environmental Protection of Active Electronics” wherein some sealing approaches are discussed to protect general electronic circuitry. A flexible sealing package is used to allow removal and reinsertion of the circuit boards, with provisions for making connections. The package is not hermetically sealed and can introduce moisture and contaminants. Furthermore, the sealing is not for CPV modules that require high quality light transmission through the sealants into the CPV modules, which is beyond the capabilities of flexible vinyl bags surrounding ordinary circuits. U.S. Pat. No. 5,739,463 also does not address the modern micro-solar cells that are in increasing use and CPV modules with their vulnerabilities to pressure changes within sealed environments.

U.S. Pat. No. 4,572,846 to Robert Foss, et al. entitled “Method Of Hermetically Sealing Electronic Packages” discusses electronic packages, particularly finished packages with leaky welds, which are hermetically sealed by vapor deposition of a polymer film through a sealable port.

### SUMMARY

Embodiments of the present invention use a flexible chamber connected to the solar module such that as the air inside expands or contracts, the flexible chamber expands and contracts to maintain substantially uniform pressure inside the module. The flexible chamber is typically made from a flexible metalized film with a very low water vapor transmission rate. In this way the module can remain sealed from water penetration and yet maintain an approximately constant internal pressure during thermal excursions. This expansion chamber may be combined with a desiccant such that, as air moves into the expansion chamber, it passes over the desiccant, which removes moisture that has penetrated into the sealed module. Thus, the air inside the module is kept dry even if small amounts of moisture penetrate the module seals.

In particular, according to some embodiments of the present invention, a concentrator-type photovoltaic device includes at least one light receiving module having a plurality of photovoltaic devices therein, and a pressure regulating device comprising a volume-adjustable chamber that is pneumatically coupled to the at least one light receiving module. The volume-adjustable chamber may be configured to expand and contract in response to temperature fluctuations within the at least one light receiving module.

In some embodiments, the at least one light receiving module and the pressure regulating device may be hermetically sealed.

In some embodiments, the volume-adjustable chamber may be an expansion bag. A combined volume of the expansion bag and the at least one light receiving module may be greater than about 1.5 times a volume of the at least one light receiving module.

In some embodiments, the volume-adjustable chamber may be a flexible metallized film. In further embodiments, the volume-adjustable chamber may be a metallized expansion bag;

In some embodiments, the volume-adjustable chamber may be a flexible, expandable chamber integrated into a sidewall of the at least one light receiving module.

In some embodiments, the pressure regulating device may include a desiccant coupled to the at least one light receiving module and the volume-adjustable chamber.

In some embodiments, the volume-adjustable chamber may have a bellows configuration.

In some embodiments, the pressure regulating device may include an oxygen scavenger pneumatically coupled between the volume-adjustable chamber and the at least one light receiving module.

In some embodiments, the volume-adjustable may be a metallized expansion coil. The metallized expansion coil may form an expansion bag.

In some embodiments, the at least one light receiving module may be an array of light receiving modules that are pneumatically coupled in common to the volume-adjustable chamber.

According to further embodiments of the present invention, a photovoltaic device includes at least one light receiving module having at least one photovoltaic cell therein. A pressure regulating device comprising a volume-adjustable chamber is pneumatically coupled to the at least one light receiving module, and a desiccant is pneumatically coupled in series between the at least one light receiving module and the volume-adjustable chamber.

In some embodiments, the desiccant may be provided within a replaceable cartridge.

In some embodiments, the photovoltaic device may further include a regenerative gas drier pneumatically coupled to the desiccant. For example, the regenerative gas drier may be a heat exchanger. The photovoltaic device may further include a heat sink thermally coupled to the at least one photovoltaic cell and the heat exchanger.

According to still further embodiments of the present invention, a photovoltaic device includes an array of light receiving modules having photovoltaic cells therein. A pressure regulating device is pneumatically coupled to the array of light receiving modules. The pressure regulating device comprises a volume-adjustable chamber configured to expand and contract in response to temperature fluctuations within the array of light receiving modules. A desiccant is pneumatically coupled to said array of light receiving modules and the volume-adjustable chamber.

In some embodiments, the desiccant may include first and second desiccant packs pneumatically coupled to a first valve network. The first valve network may be configured to pneumatically connect the first and second desiccant packs to the array of light receiving devices in an alternating one-at-a-time sequence.

In some embodiments, a moisture transfer device may be pneumatically coupled to the first valve network. The moisture transfer device may be a breathable membrane configured to support unidirectional transfer of moisture from the first valve network to an external ambient.

In some embodiments, each of the first and second desiccant packs may include a respective heating coil. Each of the first and second desiccant packs may be housed within a replaceable cartridge.

In some embodiments, the first valve network may be pneumatically coupled in series between the array and the desiccant. The photovoltaic device may further include a second valve network pneumatically coupled in series between the desiccant and the volume-adjustable chamber. The second valve network may be configured to pneumatically connect the first and second desiccant packs to the volume-adjustable chamber in the alternating one-at-a-time sequence. The first and/or second valve networks may include a plurality of bistable solenoid valves.

In some embodiments, the volume-adjustable chamber may be a flexible, expandable chamber attached to the backside of each of the modules in the array to allow close packing of the modules.

Other devices and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1 is a block diagram illustrating a sealed module connected to an expandable chamber (expansion chamber) by a tube in accordance with some embodiments. A desiccant tube can be added to dry the air as it moves from the module to the expansion chamber.

FIG. 2 is a photograph illustrating an embodiment according to FIG. 1 reduced to practice, using an expansion bag made from metalized flexible film.

FIG. 3 is a block diagram illustrating how the expandable chamber can be integrated into the sidewall of the module.

FIG. 4 is a photograph illustrating an embodiment according to the integrated expandable chamber of FIG. 3 reduced to practice.

FIG. 5 is a block diagram illustrating an expandable chamber according to some embodiments in the form of a bag that unrolls-uncoils when inflated by pressure increases and retracts with pressure drops.

FIG. 6 is a block diagram illustrating an expandable chamber according to some embodiments in the form of a metal bellows unit.

FIG. 7 is a block diagram illustrating an array of modules that are connected by tubing to a common expansion chamber in accordance with some embodiments. A desiccant pack can be added to dry air as it moves from the module to the common expansion bag.

FIG. 8A is a schematic view of a photovoltaic device according to some embodiments of the invention.

FIG. 8B is a schematic view of a photovoltaic device according to some embodiments of the invention.

### DETAILED DESCRIPTION OF EMBODIMENTS OF THE INVENTION

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entireties.

Some discoveries that led to the invention were made in the course of trying different ways of sealing out moisture and other contaminants in concentrator photovoltaic (CPV) modules, and striving to find a viable solution to regulating the pressure inside sealed CPV modules, such that the module pressure is equal to the atmospheric pressure at all times as the module heats up and cools down, while also maintaining low humidity in the module by coupling the air movement with a desiccant. Thus, some embodiments of the present invention involve the use of a volume adjustable expansion bag that is pneumatically coupled to a sealed CPV module.

In concentrator photovoltaic (CPV) modules, it is desirable to seal out moisture to prevent water condensation inside the module. However, if the module is completely sealed, there will be significant pressure changes as the module heats up in the sun and cools down at night. This can be understood by observing Charles' Law, which states:

$$\frac{{V}_{1}}{{T}_{1}} = \frac{{V}_{2}}{{T}_{2}}$$

where V1 is the volume of the module at temperature T1, and V2 is the volume of the module plus expansion bag at temperature T2. If the initial volume and the temperature extremes are known, then the final volume can be calculated by:

$${V}_{2} = \frac{{T}_{2}}{{T}_{1}} \cdot {V}_{1}$$

Typically, the temperature extremes encountered in photovoltaic applications are 233 Kelvin to 358 Kelvin. Thus, V2 will be 1.54 times V1 in order to keep the pressure essentially uniform within the combined module/expansion bag. As discussed above, pressure changes can distort the module lens array and cause misalignment of the optics, which results in loss of power.

Accordingly, some embodiments of the present invention use a flexible expansion chamber connected to the concentrator photovoltaic (CPV) solar module such that, as the air inside expands or contracts, the flexible chamber can expand and contract to maintain substantially uniform pressure inside the module. The flexible chamber can be made from a flexible metallized film with a very low water vapor transmission rate. In this way, the module can remain sealed from water penetration and yet maintain substantially uniform internal pressure during thermal excursions. In particular, in the above equations, V2 may be 1.54 times V1 in order to keep the pressure uniform within the combined module/expansion chamber. This expansion chamber may be combined with a desiccant and/or oxygen scavenger, such that, as air moves into the expansion chamber, it passes over the desiccant and/or oxygen scavenger to remove moisture and/or oxygen that has penetrated into the sealed module. This allows the air inside the module to be kept dry and oxygen free, even if small amounts of water or oxygen penetrate the module seals.

The terms “Expandable Chamber,” “Expansion Chamber” and “Expansion Bag” are herein used as essentially interchangeable, as best suited in context and with respect to the figures. Also, the term “hermetic seal” is used herein to refer to a seal which, for practical purposes, is considered airtight. In electronics, a hermetic seal may be used with reference to scaled enclosures of electronic parts that are designed and intended to secure against the entry of water vapor and foreign bodies in order to maintain the proper functioning and reliability of their contents.

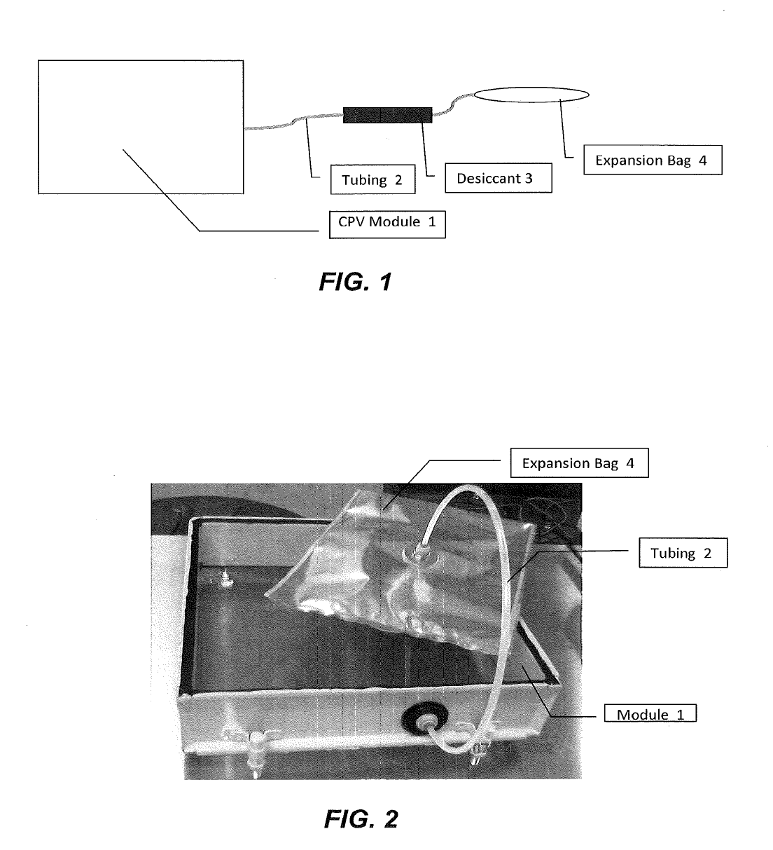

FIG. 1 illustrates an example embodiment of the present invention. As shown in FIG. 1, a sealed module 1 is connected to an expansion chamber 4 by a tube 2. The module 1 is a hermetically sealed light receiving module having a plurality of concentrator-type photovoltaic (CPV) devices therein. The expansion chamber 4 is a volume-adjustable chamber that is pneumatically coupled to the module 1 by the tube 2 and expands and contracts in response to temperature fluctuations, providing a pressure regulating device. In some embodiments, the module 1 may further include a heat sink and/or other device to lessen the possible variation in volume experienced by the expansion chamber 4. A desiccant 3 coupled between the module 1 and the expansion chamber 4 will dry the air or gas in tube 2 as it moves from module 1 to expansion chamber 4. The air or gas flow in tube 2 is driven by thermal cycles (for example, daily thermal cycles) that cause the air or gas to flow over the desiccant 3 to effectively dry the gas.

FIG. 2 is a photograph illustrating the concept of the embodiment of FIG. 1 reduced to practice. In particular, as shown in FIG. 2, a separate expansion bag 4 made from a flexible metallized flexible film is connected to a sealed module 1 by a tube 2.

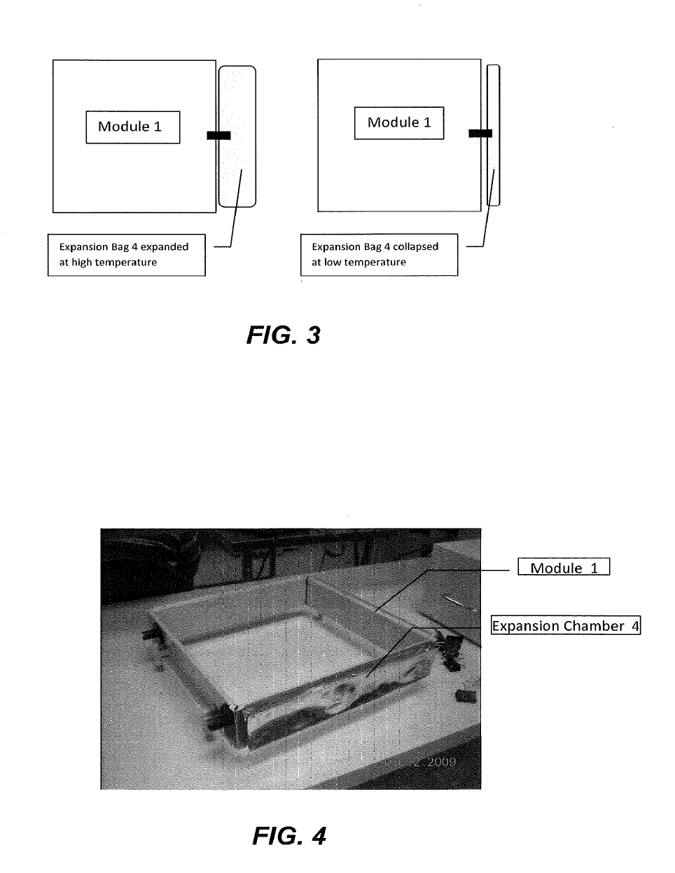

FIG. 3 illustrates an example embodiment of the present invention in which the expansion bag 4 is integrated into or otherwise attached to the sidewall of the module 1. As shown in FIG. 3, the expansion bag 4 expands with heat increase (shown at left) and contracts with heat decrease (shown at right) per Charles Law, as discussed above.

FIG. 4 is a photograph illustrating the concept of the embodiment of FIG. 3 reduced to practice. In particular, as shown in FIG. 4, the expansion chamber 4 is integrated directly on a sidewall of module 1. The expansion chamber 4 thereby expands with heat increase and contracts with heat reduction.

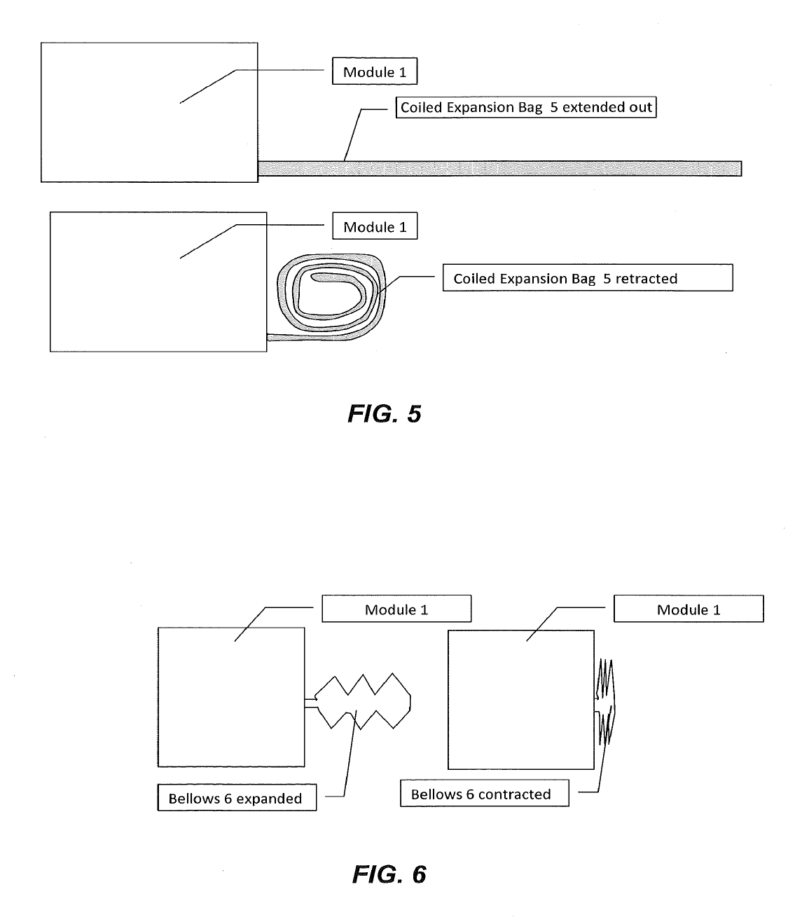

FIG. 5 illustrates an example embodiment of the present invention in which the expansion chamber is implemented as a coiled expansion bag 5. In particular, as shown in FIG. 5, module 1 is provided with an attached expandable chamber in the form of a coiled expansion bag 5 that unrolls-uncoils (shown at top) when inflated by pressure increases, and retracts into a coiled shape (shown at bottom) with pressure drops.

FIG. 6 illustrates an example embodiment of the present invention in which the expansion chamber is implemented as expandable metal bellows 6. In particular, as shown in FIG. 6, module 1 is provided with an expandable chamber in the form of a metal bellows 6 that expands with heat increase (shown at left) and contracts with heat reduction (shown at right).

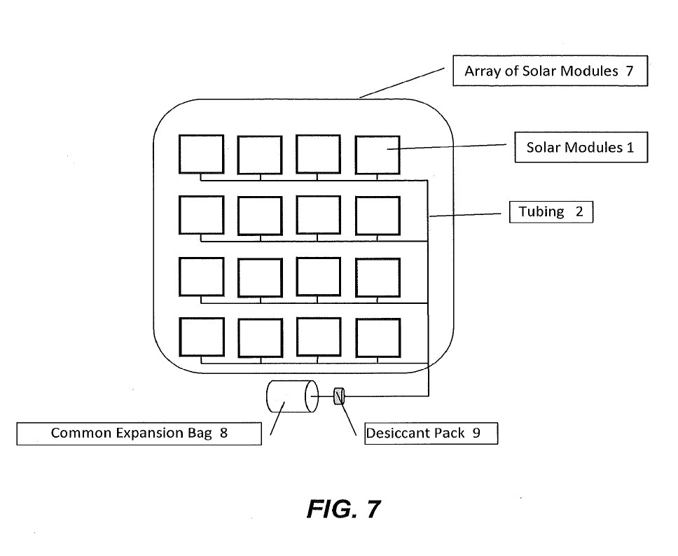

FIG. 7 shows an array of solar modules 7 according to some embodiments. Referring to FIG. 7, the array 7 includes multiple solar modules 1, with all solar modules 1 of the array 7 linked by tubing 2 to a common expansion bag 8. A desiccant pack 9 is added to dry the air or gas as it moves from modules 1 to common expansion bag 8. The common expansion bag 8 expands with heat and contracts with heat reduction as described above to maintain a stable pressure. The air or gas flow in tube 2 is driven by daily thermal cycles that cause the air or gas to flow over the desiccant 3 to effectively dry the gas. In some embodiments, the expansion bag 8 may be attached to the backside of the modules 1 to allow close packing of modules 1 on tracker frames.

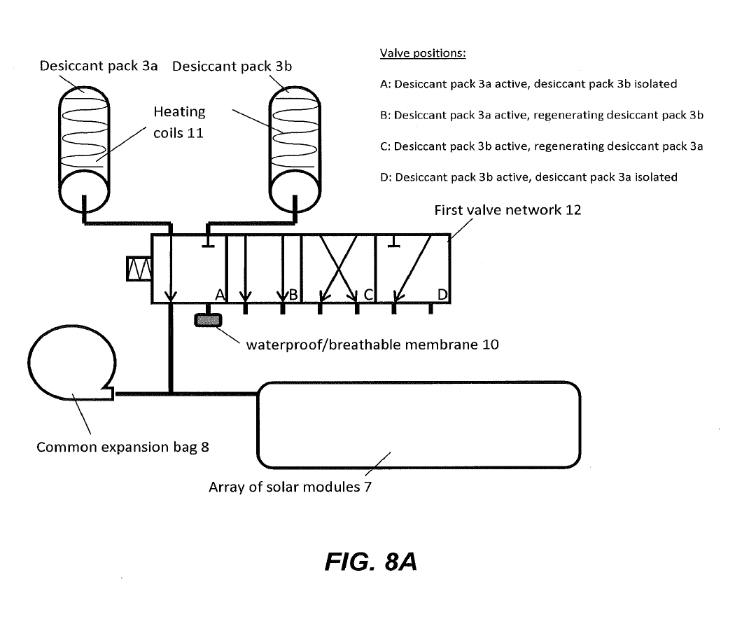

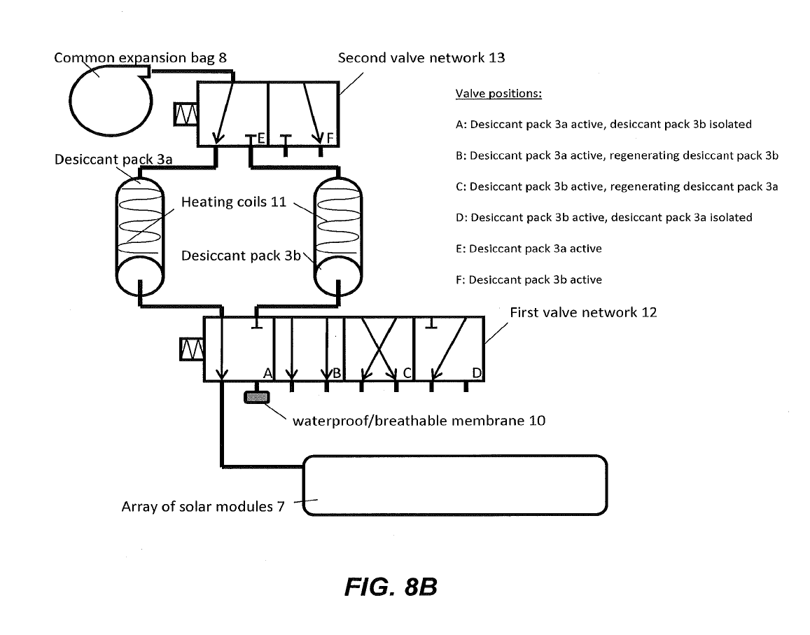

FIG. 8A illustrates a photovoltaic device according to some embodiments of the present invention. The photovoltaic device of FIG. 8A includes an array of solar modules 7. The array 7 may include respective pluralities of concentrator-type photovoltaic devices within each module 1. The array 7 is pneumatically coupled to a common expansion bag 8, which may be a metallized expansion bag in some embodiments of the invention. The level of ambient moisture within the array of solar modules 7 may be maintained below a desired threshold level by pneumatically coupling a plurality of desiccant packs (shown as pack 3a, pack 3b) to the ambient sealed within the expansion bag 8 and module array 7. As illustrated in FIG. 8A, each desiccant pack includes heating coils 11, which operate to liberate moisture from within the desiccant when heated.

The pneumatic coupling between the desiccant packs 3a, 3b and the ambient sealed within the expansion bag 8 and module array 7 is provided by a first valve network 12, which is shown as having one of four possible configurations (i.e., valve positions). These configurations are highlighted by the reference characters A, B, C and D. Under valve configuration A, desiccant pack 3a is pneumatically coupled to the common expansion bag 8 and module array 7, and desiccant pack 3b is isolated. Under valve configuration B, desiccant pack 3a is pneumatically coupled to the common expansion bag 8 and module array 7, but desiccant pack 3b is pneumatically coupled to a moisture transfer device 10, which is illustrated as a waterproof/breathable membrane, such as Gore-Tex®. The moisture transfer device 10 preferably supports unidirectional moisture transfer from within desiccant pack 3b, during heating, to an external environment (e.g., atmosphere) in which the sealed array of solar modules is operating. Under valve configuration C, desiccant pack 3b is pneumatically coupled to the common expansion bag 8 and module array 7, but desiccant pack 3a is pneumatically coupled to the moisture transfer device 10. This moisture transfer device 10 preferably supports unidirectional moisture transfer from within desiccant pack 3a, during heating, to the external environment. Under valve configuration D, desiccant pack 3b is pneumatically coupled to the common expansion bag 8 and module array 7, and desiccant pack 3a is isolated.

FIG. 8B illustrates a photovoltaic device according to further embodiments of the present invention. The photovoltaic device illustrated by FIG. 8B is similar to the photovoltaic device of FIG. 8A; however, the network of desiccant packs 3a and 3b is pneumatically coupled in series between the array of solar modules and the common expansion bag using the first valve network 12 (described above with reference to FIG. 8A) in combination with a second valve network 13. The second valve network 13 is illustrated as having one of two possible configurations, which are highlighted by the reference characters E and F. Under valve configuration E, the desiccant pack 3a is pneumatically coupled in series between the common expansion bag 8 and the array of solar modules 7, and the desiccant pack 3b is isolated. In contrast, under valve configuration F, the desiccant pack 3b is pneumatically coupled in series between the common expansion bag 8 and the array of solar modules 7, and the desiccant pack 3a is isolated. This series pneumatic connection may yield a greater level of moisture extraction by the desiccant packs relative to the embodiment illustrated by FIG. 8A.

Isolation of Pack 3a and Pack 3b can be accomplished by valve networks 12, 13 having manually operated valves. However, the isolation of Pack 3a and Pack 3b may be achieved in some embodiments by using bistable solenoid valves or similar devices (not shown) in the valve networks 12 and/or 13. The bistable solenoid valves will latch in the desired open or closed positions based on sensed conditions in the sealed environment, based on programmed signals (such as from a Programmable Logic Controller), and/or based on manual activation. Packs 3a and 3b can each be removed for replacement, upon isolating the pack to be removed, by shutting off its isolating valve, if manually operated valves are used in the valve networks 12 and/or 13. Similarly, when bistable solenoid valves or similar devices are used in the valve networks 12 and/or 13, they can be set to their closed position to isolate the pack 3a, 3b to be replaced.

Accordingly, as described in detail above with reference to FIGS. 1 to 8, embodiments of the present invention may include an expandable chamber communicating with one or more solar modules to allow gas flow to and from one or more solar modules into the expandable chamber, whereby the gas expands and contracts with changing temperature, thereby expanding and contracting the expandable chamber.

In some embodiments, the expandable chamber may be combined with a desiccant, such that the gas flow between the one or more solar modules and the expandable chamber will be over the desiccant and cause the gas to be dried. The gas flow is driven by daily thermal cycles that cause the gas flow over the desiccant to effectively dry the gas. A regenerative gas drier can be used to keep the desiccant in peak active state. The regenerative gas drier can be used in conjunction with a control for maintaining the desired operation. The regenerative gas drier would include an inlet and outlet. A simple regenerative drier can be a heat exchanger tapping a controlled amount of heat from the electronic circuitry or the circuitry's heat sinks to regenerate the desiccant, which can be provided as one or more desiccant packages. The desiccant package can be provided with connections or valves that facilitate replacement of the desiccant package as needed. This would be particularly suited when the desiccant package is in the tube leading to an expansion chamber that is not directly integrated with the sealed module or array of modules. Another method for regenerating the desiccant is to employ a timed or controlled electric heater disposed with the desiccant package. The desiccant package can be equipped with a venting valve or outlet to allow discharge of moisture released from the desiccant package.

In some embodiments, the expandable chamber may be constructed from materials with very low moisture vapor transmission rate to prevent moisture ingress into the module.

In some embodiments, the expandable chamber may be combined with an oxygen scavenger, such that gas flow between the one or more modules and the expandable chamber will be over the oxygen scavenger and cause the gas to be purged of oxygen, thereby extending life of components inside module.

Some of the elements that form the above embodiments and other embodiments discussed with reference to FIGS. 1 to 8 above may include a flexible, expandable chamber that forms a compact shape when deflated allowing for easy transport and storage; a flexible, expandable chamber constructed of thin metal in a bellows configuration; a flexible, expandable chamber integrated into the wall of a module or module arrays; a flexible, expandable chamber attached to the backside of modules to allow close packing of modules on tracker frames; and/or an array of modules joined to a common expansion bag.

As used herein, the term “concentrated photovoltaic” refers to a system that concentrates electromagnetic radiation/sunlight from the sun to a spot with irradiance greater than 1000 W/m² and generates electrical power from the resulting concentrated electromagnetic radiation. Also, the term “solar cell” refers to a photovoltaic device that is used under the illumination of sunlight to produce electrical power. Solar cells contain semiconductors with a band-gap and at least one p-n junction. Typical compositions of a solar cell may include silicon, germanium, or compound semiconductors such as gallium arsenide (GaAs), aluminum-gallium arsenide (AlGaAs), indium-gallium arsenide (InGaAs), aluminum-gallium-indium-arsenide (AlInGaAs), gallium-indium phosphide (GaInP), aluminum-indium phosphide (AlInP), aluminum-gallium-indium phosphide (AlGaInP), and combinations there-of. The term “micro-solar cell” refers to a solar cell having a total surface area smaller than 1 mm². “Receiver” refers to a group of one or more solar cells and secondary optics that accepts concentrated sunlight and incorporates means for thermal and electric energy transfer. “Module” refers to a group of receivers, optics, and other related components, such as interconnection and mounting that accepts sunlight.

The invention has been described in detail above with reference to particular embodiments thereof and, although specific terms are employed, they are used in a generic and descriptive sense only and not for purposes of limitation. Thus, it should be understood that variations and modifications could be effected within the spirit and scope of the invention as set forth by the following claims.

1. A concentrator-type photovoltaic device, comprising:
at least one light receiving module comprising an enclosure having an internal volume including a plurality of photovoltaic devices therein; and
a pressure regulating device comprising a volume-adjustable chamber that is external to the enclosure and is pneumatically coupled to the internal volume of the enclosure.

2. The photovoltaic device of claim 1, wherein the at least one light receiving module and the pressure regulating device are hermetically sealed.

3. The photovoltaic device of claim 2, wherein the volume-adjustable chamber comprises an expansion bag.

4. The photovoltaic device of claim 3, wherein a combination of a volume of the expansion bag and the internal volume of the enclosure is greater than about 1.5 times the internal volume of the enclosure.

5. The photovoltaic device of claim 1, wherein the volume-adjustable chamber comprises a flexible metallized film.

6. The photovoltaic device of claim 1, wherein the volume-adjustable chamber comprises a metallized expansion bag.

7. The photovoltaic device of claim 6, wherein the pressure regulating device comprises a desiccant pneumatically coupled to the at least one light receiving module and the volume-adjustable chamber.

8. The photovoltaic device of claim 1, wherein the pressure regulating device comprises a desiccant therein.

9. The photovoltaic device of claim 1, wherein the volume-adjustable chamber comprises bellows.

10. The photovoltaic device of claim 1, wherein said pressure regulating device comprises an oxygen scavenger pneumatically coupled to the volume-adjustable chamber.

11. The photovoltaic device of claim 1, wherein the volume-adjustable chamber comprises a metallized expansion coil.

12. The photovoltaic device of claim 1, wherein the volume-adjustable chamber comprises a flexible, expandable chamber attached to a wall of the enclosure.

13. The photovoltaic device of claim 1, wherein the at least one light receiving module comprises an array of light receiving modules comprising enclosures having respective internal volumes that are pneumatically coupled in common to the volume-adjustable chamber.

14. A photovoltaic device, comprising:
at least one light receiving module comprising an enclosure having an internal volume including at least one photovoltaic cell therein;
a pressure regulating device comprising a volume-adjustable chamber
that is external to the enclosure and is pneumatically coupled to the internal volume of the enclosure; and
a desiccant pneumatically coupled in series between the enclosure and the volume-adjustable chamber.

15. The photovoltaic device of claim 14, wherein the desiccant is provided within a replaceable cartridge.

16. The photovoltaic device of claim 14, further comprising a regenerative gas drier pneumatically coupled to the desiccant.

17. The photovoltaic device of claim 16, wherein the regenerative gas drier comprises a heat exchanger.

18. The photovoltaic device of claim 17, further comprising a heat sink thermally coupled to the at least one photovoltaic cell and the heat exchanger.

19. A photovoltaic device, comprising:
an array of light receiving modules having photovoltaic cells therein;
a pressure regulating device external to the light receiving modules of the array and pneumatically coupled to respective internal volumes of the light receiving modules of the array, the pressure regulating device comprising a volume-adjustable chamber configured to expand and contract in response to temperature fluctuations within the light receiving modules of the array; and
a desiccant pneumatically coupled to the array of light receiving modules and the volume-adjustable chamber.

20. The photovoltaic device of claim 19, wherein the desiccant comprises first and second desiccant packs pneumatically coupled to a first valve network, and wherein the first valve network is configured to pneumatically connect the first and second desiccant packs to the light receiving modules in an alternating one-at-a-time sequence.

21. The photovoltaic device of claim 20, further comprising a moisture transfer device pneumatically coupled to the first valve network.

22. The photovoltaic device of claim 21, wherein the moisture transfer device comprises a breathable membrane configured to support unidirectional transfer of moisture from the first valve network to an external ambient.

23. The photovoltaic device of claim 20, wherein each of the first and second desiccant packs comprises a respective heating coil.

24. The photovoltaic device of claim 20, wherein each of the first and second desiccant packs is housed within a replaceable cartridge.

25. The photovoltaic device of claim 20, wherein the first valve network is pneumatically coupled in series between the array and the desiccant, and further comprising a second valve network pneumatically coupled in series between the desiccant and the volume-adjustable chamber, wherein the second valve network is configured to pneumatically connect the first and second desiccant packs to the volume-adjustable chamber in the alternating one-at-a-time sequence in conjunction with the first valve network.

26. The photovoltaic device of claim 25, wherein the first and/or second valve networks comprise a plurality of bistable solenoid valves.

27. A photovoltaic device, comprising:
an array of light receiving modules having photovoltaic cells therein;
first and second desiccant packs external to the light receiving modules; and
a valve network pneumatically coupling the first and second desiccant packs to the light receiving modules, wherein the valve network is operable to pneumatically connect the first and second desiccant packs to respective internal volumes of the light receiving modules of the array in an alternating one-at-a-time sequence.

28. The device of claim 27, further comprising:
a moisture transfer device pneumatically coupled to the valve network, wherein the moisture transfer device comprises a breathable membrane configured to support unidirectional transfer of moisture from the valve network to an external ambient,
wherein the first valve network is operable to either isolate or pneumatically connect one of the first and second desiccant packs to the moisture transfer device when an other of the first and second desiccant packs is pneumatically connected to the respective internal volumes of the light receiving modules of the array in the alternating one-at-a-time sequence.

29. The device of claim 28, further comprising:
a pressure regulating device external to the light receiving modules of the array and pneumatically coupled to the respective internal volumes of the light receiving modules, the pressure regulating device comprising a volume-adjustable chamber configured to expand and contract in response to temperature fluctuations within the light receiving modules of the array.

30. The device of claim 29, wherein the valve network comprises a first valve network pneumatically coupled in series between the light receiving modules of the array and the first and second desiccant packs, and further comprising:
a second valve network pneumatically coupled in series between the first and second desiccant packs and the volume-adjustable chamber, wherein the second valve network is operable to pneumatically connect the first and second desiccant packs to the volume-adjustable chamber in an alternating one-at-a-time sequence in conjunction with operation of the first valve network.
